(19) United States
(12) Patent Application Publication
(10) Pub. No.: US 2019/0249906 A1
(43) Pub. Date: Aug. 15, 2019

(54) SOLAR TRACKING SYSTEM AND SOLAR TRACKING METHOD

(71) Applicant: Chien-Hsing WU, Keelung (TW)

(72) Inventors: Chien-Hsing WU, Keelung (TW); Hui-Chiao WANG, Keelung (TW)

(21) Appl. No.: 15/964,675

(22) Filed: Apr. 27, 2018

(30) Foreign Application Priority Data
Feb. 14, 2018 (TW) 107105473

(51) Int. Cl. F24S 50/20; G01S 19/14; G05D 3/10; F24S 30/40; H01L 31/042

(52) U.S. Cl. CPC F24S 50/20; G01S 19/14; H01L 31/042; F24S 30/40; G05D 3/105

(57) ABSTRACT

The disclosure provides a solar tracking system including a first satellite signal receiver, a second satellite signal receiver, at least one solar panel, and a control module. The first satellite signal receiver is disposed on a part of a mobile vehicle. The second satellite signal receiver is disposed on another part of the mobile vehicle. The at least one solar panel is movably disposed on the mobile vehicle. The control module, electrically is connected to the first satellite signal receiver and the second satellite signal receiver to obtain a line of bearing passing through the first and the second satellite signal receivers according to coordinates of the first and the second satellite signal receivers, thereby pointing the solar panel toward the Sun according to the line of bearing and a current position of the Sun. In addition, the disclosure also provides a solar tracking method.

### CROSS-REFERENCE TO RELATED APPLICATIONS

This non-provisional application claims priority under 35 U.S.C. § 119(a) on Patent Application No(s). 107105473 filed in Taiwan, R.O.C. on Feb. 14, 2018, the entire contents of which are hereby incorporated by reference.

### TECHNICAL FIELD

The disclosure relates to a solar tracking system and a solar tracking method, more particularly to a solar tracking system and a solar tracking method that are applicable to a mobile vehicle.

### BACKGROUND

In recent years, with the rise of environmental awareness and the issue of the energy shortage, solar energy gradually becomes an important alternative energy source. One of the reasons is that the solar energy is sustainable and totally inexhaustible. It is also a non-polluting source of energy and it does not emit any greenhouse gases when producing electricity. In addition, solar energy generators can be integrated into all aspects of lift. For example, solar energy collecting devices, such as solar panels, can be mounted on buildings, making the buildings itself an energy source. Even more, the solar panels can be mounted on mobile vehicles, such as automobiles and ships.

The solar panel which is applied on the mobile vehicles must have an ability of tracking sunlight. In a conventional solar tracking system, photoresistance is usually employed for tracking sunlight. However, the photoresistance has a relatively high sensing error and frequently fails to accurately orient the solar panel toward the sun. For instance, when there are clouds or aircraft passing over and blocking the sunlight, or when the mobile vehicle is passing through under a bridge so that the sunlight is temporarily blocked, it may cause a sensing error. Furthermore, the photoresistance has a slow response time, and it causes the solar tracking system to have a difficulty to promptly determine the position of the Sun, resulting in low accuracy in orienting the solar panel.

### SUMMARY

Accordingly, the present disclosure provides a solar tracking system and a solar tracking method capable of solving the aforementioned problems.

One embodiment of the disclosure provides a solar tracking system adapted to be applied to a mobile vehicle. The solar tracking system includes a first satellite signal receiver, a second satellite signal receiver, at least one solar panel, and a control module. The first satellite signal receiver is adapted to be disposed on a part of the mobile vehicle. The second satellite signal receiver is adapted to be disposed on another part of the mobile vehicle. The at least one solar panel is adapted to be movably disposed on the mobile vehicle. The control module, electrically is connected to the first satellite signal receiver and the second satellite signal receiver so as to obtain a line of bearing passing through the first satellite signal receiver and the second satellite signal receiver according to coordinates of the first satellite signal receiver and the second satellite signal receiver, thereby pointing the at least one solar panel toward the Sun according to the line of bearing and a current position of the Sun.

One embodiment of the disclosure provides a solar tracking method adapted to be applied to a mobile vehicle. The solar tracking method includes performing a satellite signal receiving step, performing a sun position determining step, and performing a solar panel adjusting step. The satellite signal receiving step includes: obtaining a first current coordinate information and a first current time information via a first satellite signal receiver and obtaining a second current coordinate information and a second current time information via a second satellite signal receiver, wherein the first satellite signal receiver and the second satellite signal receiver are disposed at different places on the mobile vehicle. The sun position determining step includes: requesting a sun position information from a storage unit by a control module according to the first current coordinate information and the first current time information or the second current coordinate information and the second current time information. The solar panel adjusting step includes: obtaining a line of bearing passing through the first satellite signal receiver and the second satellite signal receiver by the control module according to the first current coordinate information and the second current coordinate information; and pointing at least one solar panel toward the Sun by the control module according to the sun position information and a relationship between the sun position information and the line of bearing.

### BRIEF DESCRIPTION OF THE DRAWINGS

The present disclosure will become better understood from the detailed description given hereinbelow and the accompanying drawings which are given by way of illustration only and thus are not intending to limit the present disclosure and wherein:

FIG. 1 is a schematic view of a solar tracking system on a mobile vehicle according to one embodiment of the disclosure;

FIGS. 2-3 are flowcharts showing steps of operating the solar tracking system in FIG. 1;

FIG. 4 is a flowchart showing steps of operating a solar tracking system according to another embodiment of the disclosure; and

FIG. 5 shows different scenarios that the mobile vehicle in FIG. 1 is sailing on the sea.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known main structures and devices are schematically shown in order to simplify the drawing.

In addition, embodiments of the present disclosure will be disclosed below by way of illustration, and for the sake of clarity, many practical details will be described in the following description. However, it should be understood that these practical details are not intended to limit the present disclosure. In addition, to simplify the drawings, some conventional structures and components are schematically illustrated in the drawings, and some of the drawings omit structures (wires, cables, etc.) so as to keep the drawing clean and simple.

Furthermore, unless being specifically defined, all terms used herein, including technical and scientific terms, have their common meanings, as those whose meanings can be understood by those skilled in the art. Further, the definition of the above terms should be interpreted in the present specification as having the same meaning as the technical field related to the present disclosure. Unless specifically defined, these terms are not to be interpreted as being too idealistic or formal.

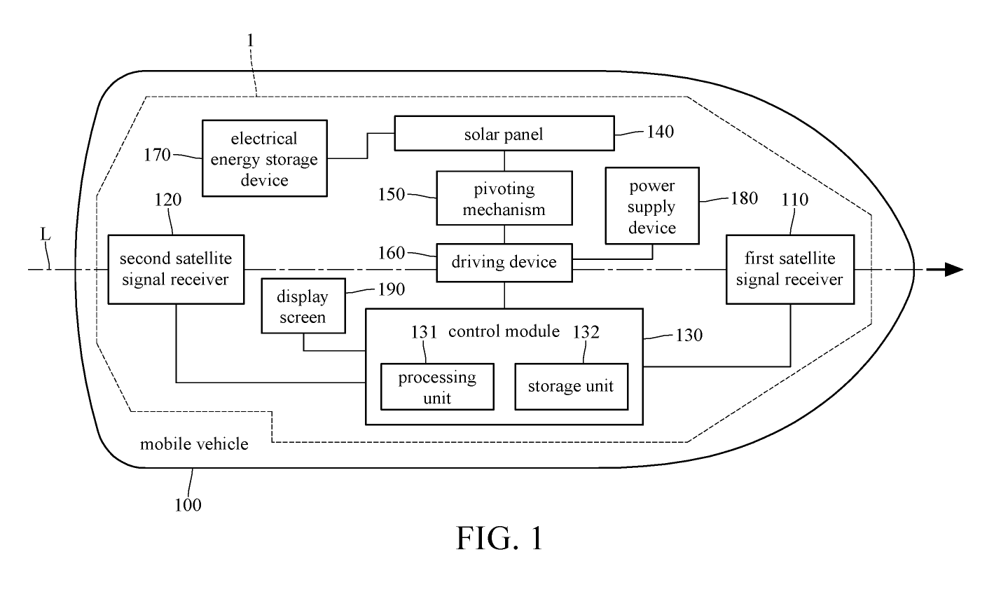

Firstly, please refer to FIG. 1, FIG. 1 is a schematic view of a solar tracking system on a mobile vehicle according to one embodiment of the disclosure. This embodiment provides a solar tracking system 1 which is adapted to be applied to a mobile vehicle 100. The mobile vehicle 100 is a mobile machine that transports people or cargo. For example, the mobile vehicle 100 can be a motorcycle, a car, a truck, a watercraft (ship, vessel, or boat), an aircraft or a spacecraft. In this embodiment, the mobile vehicle 100 is a ship, so it is called ‘ship 100’ in the following paragraphs.

The solar tracking system 1 includes a first satellite signal receiver 110, a second satellite signal receiver 120, a control module 130, at least one solar panel 140, a pivoting mechanism 150 and a driving device 160.

The first satellite signal receiver 110 and the second satellite signal receiver 120 are GPS Receivers that can extract and calculate geolocation and time information provided by a global positioning satellite system in order to determine the precise position and time of themself. In this embodiment, the first satellite signal receiver 110 and the second satellite signal receiver 120 are respectively disposed at the bow (or the head part) and the stern (or the tail part) of the ship 100; that is, the first satellite signal receiver 110 and the second satellite signal receiver 120 are respectively disposed at two opposite ends of the ship 100. Preferably, the first satellite signal receiver 110 and the second satellite signal receiver 120 are placed on a longitudinal direction L of the ship 100. The longitudinal direction L is an imaginary line (also called line of bearing) passing through the bow and the stern of the ship 100. In this embodiment, the longitudinal direction L is a symmetrical centerline of the ship 100, but the present disclosure is not limited to the arrangement of the first satellite signal receiver 110 and the second satellite signal receiver 120. In fact, any plane, that allows the first satellite signal receiver 110 and the second satellite signal receiver 120 to be placed separately and is horizontal to the sea surface, falls within the scope of the present disclosure. For example, in some other embodiments, the first satellite signal receiver 110 and the second satellite signal receiver 120 may be respectively placed at any two different places on the deck of the ship 100.

The control module 130 is electrically connected to the first satellite signal receiver 110 and the second satellite signal receiver 120 so as to receive the satellite signals (including longitude and latitude coordinate and time information) from the first satellite signal receiver 110 and the second satellite signal receiver 120. In more detail, in this embodiment, the control module 130 includes a processing unit 131 and a storage unit 132. The processing unit 131 is, for example, a microprocessor that can process the satellite signals; and the storage unit 132 is, for example, a memory unit that can storage one or more data bases for the processing unit 131. The data base includes information relating to the aforementioned satellite signals. For example, the position information of the Sun and the sunrise and sunset time information at a specific coordinate and time. The position information of the Sun includes the solar azimuth angle and the solar elevation angle (also called the altitude of the Sun) with respect to the observer (e.g. the satellite signal receiver).

The solar panel 140 is a device that can convert solar radiation (e.g. sunlight) into electricity. The solar panel 140 has a large and flat light-receiving surface, and this is why it is often called the solar panel. In this embodiment, the solar panel 140 is disposed on the deck of the ship 100, but the location of the solar panel 140 on the ship 100 is not restricted. In addition, the quantity of the solar panel 140 is not restricted, either. For example, in some other embodiments, there may be a plurality of solar panels 140 disposed on the ship 100, and these solar panels 140 may be arranged along the longitudinal direction L1 of the ship 100.

In more detail, the solar panel 140 is disposed on the ship 100 via the pivoting mechanism 150. The pivoting mechanism 150 includes, for example, a horizontal pivoting module and a vertical pivoting module. The horizontal pivoting module and the vertical pivoting module are able to adjust the orientation angle and the tilt angle of the solar panel 140, respectively. However, the present disclosure is not limited to the configuration of the pivoting mechanism 150.

The driving device 160 is electrically connected to the control module 130. In this embodiment, the driving device 160 is, for example, an electric motor. The driving device 160 is able to drive the pivoting mechanism 150 to pivot the solar panel 140 according to the signal from the control module 130. In order to obtain optimal solar energy from the Sun, the solar panel 140 is preferably pivoted to be perpendicular to the incoming sunlight. Specifically, a normal line of the light-receiving surface of the solar panel 140 is preferably oriented towards the Sun so as to maximize sunlight exposure.

In addition, as shown in FIG. 1, the solar tracking system 1 further includes an electrical energy storage device 170 and a power supply device 180. The electrical energy storage device 170 is, for example, a storage battery, and is electrically connected to the solar panel 140, such that the electrical energy storage device 170 is able to storage the electricity produced by the solar panel 140 for other electrical requirements on the ship 100, such as lighting devices. The power supply device 180 is, for example, an electricity generator which can produce electricity for the driving device 160. However, the power supply device 180 is optional. In some other embodiments, the solar tracking system may have no such power supply device 180; in such a case, the driving device 160 may be electrically connected to the electrical energy storage device 170 and triggered by the electricity from the solar panel 140.

Furthermore, the solar tracking system 1 further includes a display screen 190. The display screen 190 is electrically connected to the processing unit 131 of the control module 130. The display screen 190 is able to receive the coordinate and time information received by the first satellite signal receiver 110 and/or the second satellite signal receiver 120 and display it to users. However, the display screen 190 is optional.

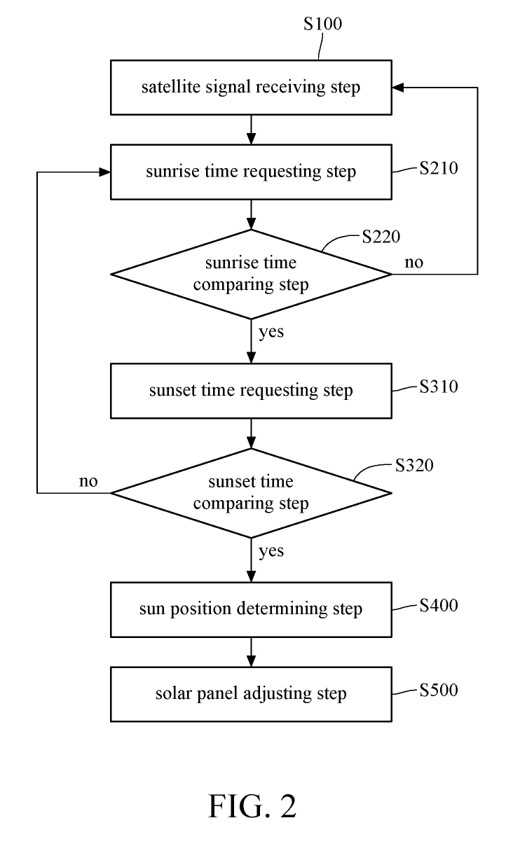

Then, the method of operating the solar tracking system 1 is explained in the following paragraphs. Please refer to FIGS. 2-3, FIGS. 2-3 are flowcharts showing steps of operating the solar tracking system in FIG. 1.

Firstly, performing a satellite signal receiving step S100. At the step S100, the control module 130 obtains a first current coordinate information and a first current time information through the first satellite signal receiver 110 and obtains a second current coordinate information and a second current time information through the second satellite signal receiver 120. In detail, the processing unit 131 of the control module 130 requests the first satellite signal receiver 110 to get the first current coordinate information and the first current time information and requests the second satellite signal receiver 120 to get the second current coordinate information and the second current time information. The first current coordinate information and the second current coordinate information respectively represent the current coordinates of different parts of the ship 100 (e.g., the bow and the stern of the ship 100). The first current time information and the second current time information respectively represent the current time (including year, month, date, hour, minute, second, etc.) of different parts of the ship 100 (e.g., the bow and the stern of the ship 100).

Then, performing a sunrise time requesting step S210. The step S210 includes: requesting a sunrise time from the database of the storage unit 132 by the control module 130 according to first current coordinate information and the first current time information or the second current coordinate information and the second current time information. Although the first satellite signal receiver 110 and the second satellite signal receiver 120 are disposed at different places, it is acceptable to take the information of one of them as the overall coordinate and time of the ship 100. Thus, the processing unit 130 of the control module 130 can obtain a latest sunrise time from the data base in the storage unit 132 according to the information provided by either the first satellite signal receiver 110 or the second satellite signal receiver 120.

Then, performing a sunrise time comparing step S220. The step S220 includes: determining whether the first current time information or the second current time information is later than or equal to the sunrise time by the control module 130. When the first current time information or the second current time information is determined to be not later than or equal to the sunrise time, the first current time information or the second current time information is determined to be earlier than the sunrise time, meaning that one on the ship cannot yet see the Sun at this moment. In such a case, the control module 130 then sequentially performs the satellite signal receiving step S100, the sunrise time requesting step S210 and the sunrise time comparing step S220 after a first predetermined period of time. The reason is that, during the first predetermined period of time, the ship 100 will keep sailing, the coordinate of the ship 100 will change, so will the sunrise time to the location of the ship 100, thus it needs to find another sunrise time which corresponds to the coordinate of the ship 100 after a while. The first predetermined period of time is, for example, one-minute, ten-minutes, twenty-minutes or one-hour time interval, but the present disclosure is not limited thereto. On the contrary, when the first current time information or the second current time information is determined to be later than or equal to the sunrise time, meaning that, at the current location, the Sun is rising or has been shining for a while. At this moment, it may need to perform a sunset time requesting step S310 to determine the sunset time.

The sunset time requesting step S310 includes: requesting a sunset time from the database of the storage unit 132 by the control module 130 according to the first current coordinate information and the first current time information or the second current coordinate information and the second current time information.

Then, performing a sunset time comparing step S320. The step S320 includes: determining whether the first current time information or the second current time information is earlier than the sunset time by the control module 130. When the first current time information or the second current time information is determined to be not earlier than the sunset time, the first current time information or the second current time information is determined to be equal to or later than the sunset time, meaning that the Sun is barely visible or invisible at the current location. In such a case, the control module 130 then sequentially performs the sunrise time requesting step S210 and the sunrise time comparing step S220 after a second predetermined period of time by the control module 130. The reason is that, during the second predetermined period of time, the ship 100 will keep sailing and waiting for the next sunrise, but the coordinate of the ship 100 will change, so will the sunrise time to the location of the ship 100, thus it needs to find another sunrise time which corresponds to the coordinate of the ship 100 after a while. Similarly, the second predetermined period of time is, for example, one-minute, ten-minutes, twenty-minutes or one-hour time interval, but the present disclosure is not limited thereto. On the contrary, when the first current time information or the second current time information is determined to be earlier than the sunset time, meaning that, at the current location, the Sun is still shining. In such a case, the control module 130 then performs a sun position determining step S400 to collect solar energy.

The sun position determining step S400 includes: requesting a sun position information from the database of the storage unit 132 by the control module 130 according to the first current coordinate information and the first current time information or the second current coordinate information and the second current time information. As for determining the location and the time information of the ship 100, the information from the first satellite signal receiver 110 and the second satellite signal receiver 120 both are acceptable to be taken as representative of the location and the time of the ship 100 although they are located at different places. Thus, the processing unit 131 of the control module 130 can obtain a sun position information from the database of the storage unit 132 according to either the first current coordinate information and the first current time information or the second current coordinate information and the second current time information. The sun position information includes the solar azimuth angle and the solar elevation angle.

Then, performing a solar panel adjusting step S500 in order to point the solar panel 140 toward the Sun. In detail, as shown in FIG. 3, the solar panel adjusting step S500 includes a step S510 and a step S520.

The step S510 includes: obtaining a line of bearing passing through both the first satellite signal receiver 110 and the second satellite signal receiver 120 by the control module 130 according to the first current coordinate information and the second current coordinate information. In detail, the ship 100 is usually in a narrow and long shape and its bow and stern may have a distance from dozens of meters to hundreds of meters, thus winds, currents or waves may easily cause the ship 100 to sway and yaw and thereby result in change in a heading direction of the ship 100. The heading direction means that a ship, boat, or vessel's head is pointing, and it represents the direction a ship, boat, or vessel is going. The change in the heading direction also changes the direction of the solar panel 140, and this leads to a tracking failure. Therefore, the heading direction of the ship 100 becomes a critical factor while adjusting the solar panel 140. Accordingly, the solar tracking system of the present disclosure utilizes the line of bearing to determine the heading direction of the ship 100. Specifically, in this embodiment, the heading direction of the ship 100 can be determined by the control module 130 according to the coordinate information (i.e., the first current coordinate information and the second current coordinate information) provided by the first satellite signal receiver 110 and the second satellite signal receiver 120. The first satellite signal receiver 110 and the second satellite signal receiver 120 are arranged along the longitudinal direction L, and the longitudinal direction L can be taken as the heading direction of the ship 100, so the line of bearing can be taken as the representative of the heading direction of the ship 100.

In some other embodiments, the first satellite signal receiver 110 and the second satellite signal receiver 120 may not be arranged along the longitudinal direction L; in such a case, the heading direction still can be determined by mathematically converting the line of bearing. That is, the heading direction of the ship 100 can be determined as long as the receivers are disposed at different places on the ship 100.

Then, the step S520 includes: pointing the solar panel 140 toward the Sun by the control module 130 according to the sun position information and the relationship between the sun position information and the line of bearing. In detail, in order to avoid the influence of the sway of the ship 100 and to maximize the solar energy collected from the solar panel 140, the direction of the solar panel 140 must be determined by considering both the sun position information and the relationship between the sun position information and the line of bearing. Thus, according to the sun position information and the relationship between the sun position information and the line of bearing, the processing unit 131 of the control module 130 is able to request the driving device 160 to drive the horizontal pivoting module and/or the vertical pivoting module of the pivoting mechanism 150 to point the solar panel 140 in the direction with the most direct sunlight.

The above is the discussion of the solar tracking method of one of the embodiments of the present disclosure, however, the sunrise time requesting step S210 to the sunset time comparing step S320 are optional. The purposes of the steps S210 to S320 are to determine the timing of solar collecting. In practical, the sunrise and the sunset may be determined by eyes. In such a case, the solar tracking method may omit the sunrise time requesting step S210 to the sunset time comparing step S320.

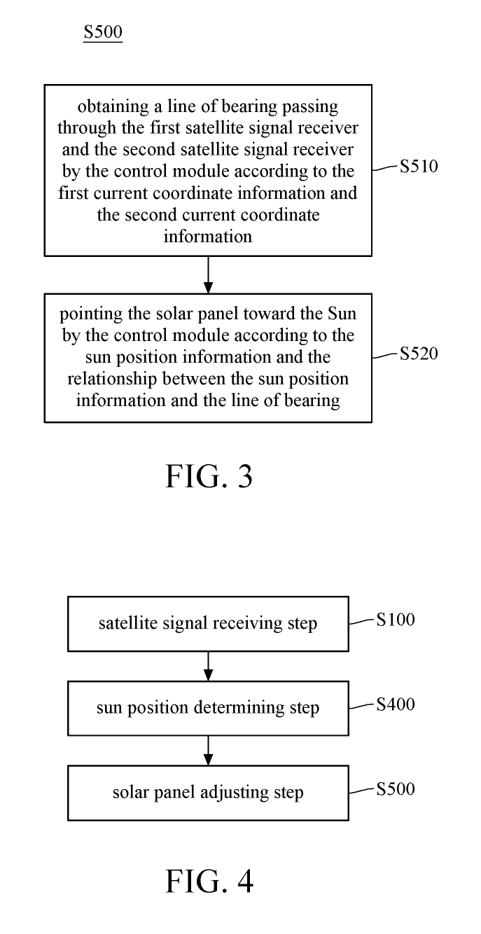

For example, please refer to FIG. 4, FIG. 4 is a flowchart showing steps of operating a solar tracking system according to another embodiment of the disclosure. In this embodiment, the solar tracking method only includes the satellite signal receiving step S100, the sun position determining step S400 and the solar panel adjusting step S500.

Then, taking a few scenarios to explain the solar tracking method of the present disclosure.

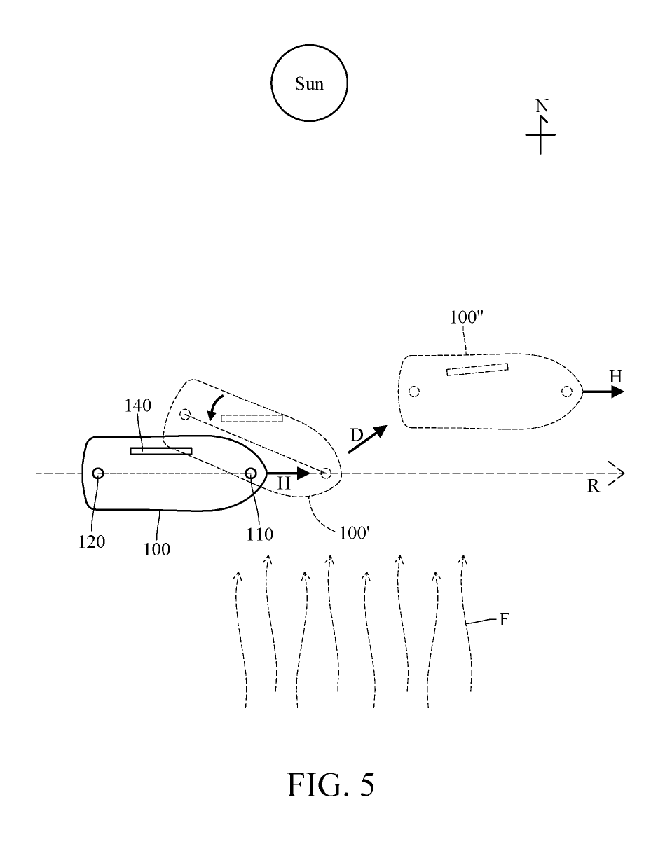

Please refer to FIG. 5, FIG. 5 shows different scenarios that the mobile vehicle in FIG. 1 is sailing on the sea. It must be understood that FIG. 5 is a top view over an area where the ship is passing through, and some of the components on the ship are omitted for the purpose of clear explanation. As shown in the figure, the ship 100 (also called the mobile vehicle) having the solar tracking system 1 attempts to sail from west to east along a predetermined route R, and there are ocean currents and winds flowing from south to north (e.g., in a direction F).

At this moment, the current coordinate of the ship 100 can be determined through the satellite signal receiving step S100, and the position of the Sun (i.e., the sun position information) can be determined through the sun position determining step S400. Then, the heading direction H of the ship 100 can be determined through the step S510. After the coordinate of the ship 100, the direction of the ship 100, and the position of the Sun are determined, the step S520 is performed in order to point the solar panel 140 toward the Sun.

Then, after the ship 100 sailing for a while, the position of the Sun may not change too much, but the heading direction of the ship 100 may be largely changed due to the ocean currents, winds or other factors (e.g., the ship 100′ in dotted-line). In this scenario, the solar panel 140 on the ship 100′ is changed into a position where it collects less solar energy. To avoid this, the control module 130 repeatedly performs the steps of the solar tracking method for every specific period of time to correct the direction of the solar panel 140. In detail, in the case of the ship 100′, although the heading direction had been largely changed due to the ocean currents or winds, the control module 130 can obtain a new line of bearing by performing the solar panel adjusting step S500 (i.e., the longitudinal direction of the ship or the current heading direction) again so as to pivoting the solar panel 140 to make it pointing toward the Sun (as shown in the arrow).

Then, in another scenario, the ship 100 may go off the predetermined route R (as the ship 100″ in dotted-line) due to the ocean currents or winds. In such a case, the solar tracking system 1 is able to update the position of the Sun with respect to itself through the aforementioned the solar tracking method in order to readjust the direction of the solar panel 140.

In comparison to the former scenario, if the ship 100′ only has one satellite signal receiver, it would not even notice the existence of the sway and the requirement of adjusting the direction of the solar panel 140 because the ship 100′ is still on the predetermined route R. Even if the position of the solar panel 140 is adjusted due to the difference in the coordinate received by the single satellite signal receivers, the adjustment is far less enough to compensate the large sway, thereby causing the failure of the solar tracking. In comparison to the latter scenario, if the ship 100 only has one satellite signal receiver for tracking the Sun, it will mistake that the heading direction is changed to the direction D and thereby largely pivoting the solar panel 140, causing the solar panel 140 to off from the optimal position. As such, it should be understood that the configuration of two single satellite signal receivers disposed at different places are able to overcome the issues due to the inherent structure of the ship 100 and the influence of the marine environment.

According to the solar tracking system and the solar tracking method as discussed in above, the position of the Sun is determined by the satellite signal receivers, thus the solar tracking system and the solar tracking method have a high immunity to different weather conditions and able to achieve a high tracking accuracy.

Also, there are at least two satellite signal receivers disposed at different places to determine the longitudinal direction of the mobile vehicle, and the longitudinal direction helps to correct the direction of the solar panel for maximizing sunlight exposure.

It will be apparent to those skilled in the art that various modifications and variations can be made to the present disclosure. It is intended that the specification and examples be considered as exemplary embodiments only, with a scope of the disclosure being indicated by the following claims and their equivalents.

What is claimed is:

1. A solar tracking system, adapted to be applied to a mobile vehicle, comprising:
a first satellite signal receiver, adapted to be disposed on a part of the mobile vehicle;
a second satellite signal receiver, adapted to be disposed on another part of the mobile vehicle;
at least one solar panel, adapted to be movably disposed on the mobile vehicle; and
a control module, electrically connected to the first satellite signal receiver and the second satellite signal receiver so as to obtain a line of bearing passing through the first satellite signal receiver and the second satellite signal receiver according to coordinates of the first satellite signal receiver and the second satellite signal receiver, thereby pointing the at least one solar panel toward the Sun according to the line of bearing and a current position of the Sun.

2. The solar tracking system according to claim 1, wherein the line of bearing is parallel to a longitudinal direction of the mobile vehicle.

3. The solar tracking system according to claim 1, wherein the mobile vehicle is a ship, a boat or a vessel, and the line of bearing is parallel to a heading direction of the mobile vehicle.

4. The solar tracking system according to claim 1, further comprising a pivoting mechanism, wherein the at least one solar panel is adapted to be movably disposed on the mobile vehicle through the pivoting mechanism.

5. The solar tracking system according to claim 1, wherein the quantity of the at least one solar panel is plural, and the solar panels are arranged along the longitudinal direction of the mobile vehicle.

6. The solar tracking system according to claim 1, wherein the first satellite signal receiver and the second satellite signal receiver are respectively disposed at two opposite ends of the mobile vehicle.

7. The solar tracking system according to claim 1, further comprising a display screen electrically connected to the control module, and the display screen configured to display the coordinates of the first satellite signal receiver and the second satellite signal receiver.

8. A solar tracking method, adapted to be applied to a mobile vehicle, comprising:
performing a satellite signal receiving step, comprising:
obtaining a first current coordinate information and a first current time information via a first satellite signal receiver and obtaining a second current coordinate information and a second current time information via a second satellite signal receiver, wherein the first satellite signal receiver and the second satellite signal receiver are disposed at different places on the mobile vehicle;
performing a sun position determining step, comprising:
requesting a sun position information from a storage unit by a control module according to the first current coordinate information and the first current time information or the second current coordinate information and the second current time information; and
performing a solar panel adjusting step, comprising:
obtaining a line of bearing passing through the first satellite signal receiver and the second satellite signal receiver by the control module according to the first current coordinate information and the second current coordinate information; and
pointing at least one solar panel toward the Sun by the control module according to the sun position information and a relationship between the sun position information and the line of bearing.

9. The solar tracking method according to claim 8, before performing the sun position determining step, further comprising:
performing a sunrise time requesting step, comprising:
requesting a sunrise time from the storage unit by the control module according to the first current coordinate information and the first current time information or the second current coordinate information and the second current time information; and
performing a sunrise time comparing step, comprising:
determining whether the first current time information or the second current time information is later than or equal to the sunrise time by the control module;
when the first current time information or the second current time information is determined to be later than or equal to the sunrise time, the sun position determining step is performed;
when the first current time information or the second current time information is determined to be not later than or equal to the sunrise time, the control module sequentially performs the satellite signal receiving step, the sunrise time requesting step, and the sunrise time comparing step after a first predetermined period of time.

10. The solar tracking method according to claim 9, before performing the sun position determining step, further comprising:
performing a sunset time requesting step, comprising:
requesting a sunset time from the storage unit by the control module according to the first current coordinate information and the first current time information or the second current coordinate information and the second current time information;
performing a sunset time comparing step, comprising:
determining whether the first current time information or the second current time information is earlier than the sunset time;
when the first current time information or the second current time information is determined to be earlier than the sunset time, the sun position determining step is performed;
when the first current time information or the second current time information is determined to be not earlier than the sunset time, the control module sequentially performs the sunrise time requesting step and the sunrise time comparing step after a second predetermined period of time.
